(19) United States
(12) Patent Application Publication
(10) Pub. No.: US 2026/0251863 A1
(43) Pub. Date: Aug. 27, 2026

(54) SEMICONDUCTOR DEVICE

(71) Applicant: PanelSemi Corporation, New Taipei City (TW)

(72) Inventors: Jeng-Long SHEU, New Taipei City (TW); Chin-Tang LI, New Taipei City (TW)

(21) Appl. No.: 19/551,455

(22) Filed: Feb. 26, 2026

Related U.S. Application Data
(60) Provisional application No. 63/763,630, filed on Feb. 26, 2025.

(51) Int. Cl. G02B 6/42; H10W 90/10

(52) U.S. Cl. CPC G02B 6/4214; G02B 6/4209; G02B 6/4239; H10W 90/10

(57) ABSTRACT

A semiconductor device includes a substrate structure, a cavity, an integrated circuit unit, an optical path, and an optical steering structure. The substrate structure includes a base material layer and a waveguide layer stacked thereon, and defines a surface. The cavity is arranged in the substrate structure, communicates with the waveguide layer and forms an opening on the surface. The integrated circuit unit is disposed on the surface and includes a photonic integrated circuit facing the opening. The optical path is formed between the photonic integrated circuit and the waveguide layer. The optical steering structure is configured in the cavity for steering the optical path, and includes a continuous surface, an optical reflective layer disposed thereon, and a light-transmitting window remaining thereon and corresponding to the waveguide layer. The optical reflective layer guides the optical path and adapt to transmission requirements of different geometries of the optical path.

### CROSS REFERENCE TO RELATED APPLICATIONS

This Non-provisional application claims priority to U.S. provisional patent application with serial number 63/763,630 filed on February 26, 2025. This and all other extrinsic materials discussed herein are incorporated by reference in their entirety.

### BACKGROUND

### Technology Field

The disclosure relates to a semiconductor device, and more particularly to a semiconductor device for optical component packaging.

### Description of Related Art

As semiconductor devices require increasing data exchange with external devices, traditional electrical signal transmission interfaces have encountered bottlenecks, including limitations in transmission speed, electromagnetic interference issues, and high power consumption challenges. Consequently, the industry has begun adopting optical communication as an alternative solution. While optical communication offers advantages such as high transmission speed, strong interference resistance, and lower power consumption, integrating optical communication into semiconductor devices still presents numerous technical challenges. The current common practice is to place optoelectronic conversion modules separately adjacent to the semiconductor chip. Although this implementation is simple, it significantly increases the overall device size. Furthermore, the lengthy electrical connection paths required between the optoelectronic conversion modules and the semiconductor chip not only increase signal delay but are also susceptible to electromagnetic interference. Additionally, the alignment between optoelectronic conversion elements and waveguides remains a critical issue, as temperature variations and mechanical stress can cause alignment shifts that affect optical coupling efficiency. Existing technologies typically require complex alignment structures and packaging methods to maintain stability, which increases manufacturing costs. Therefore, how to maintain device miniaturization while ensuring stable optical coupling has become a crucial challenge faced by semiconductor devices integrating optical communication interfaces.

### SUMMARY

One aspect of this disclosure is to provide a semiconductor device and one or more exemplary embodiments thereof, which are used to illustrate the optical coupling between the semiconductor device and external optical signals.

One aspect of this disclosure is to provide a semiconductor device and one or more exemplary embodiments thereof, which are used to illustrate the integration of an optical coupling interface in the semiconductor device, thereby facilitating the overall miniaturization of the device.

This disclosure is to provide a semiconductor device that includes a substrate structure, a cavity, an integrated circuit unit, an optical path, and an optical steering structure. The substrate structure comprises a base material layer and a waveguide layer stacked on the base material layer; the substrate structure defines a surface. The cavity is arranged in the substrate structure, communicates with the waveguide layer, and defines an opening on the surface. The integrated circuit unit is disposed on the surface and includes a photonic integrated circuit (PIC) that corresponds to and faces the opening. The optical path is formed between the photonic integrated circuit and the waveguide layer. The optical steering structure is configured in the cavity to steer the optical path. The optical steering structure includes a continuous surface, an optical reflective layer partially arranged on the continuous surface, and a light-transmitting window remained at the continuous surface and corresponding to the waveguide layer. The optical reflective layer are configured to guide the optical path from one direction to another and to adapt to different geometries of the optical path.

In one embodiment, the substrate structure defines an electrical layer on the surface.

In one embodiment, the substrate structure has a vertical electrical connection structure inside.

In one embodiment, the waveguide layer is arranged in the base material layer and is aligned with the surface of the base material layer on the same horizontal plane.

In one embodiment, the base material layer includes a rigid layer and a flexible layer stacked over the rigid layer.

In one embodiment, the waveguide layer includes a polymer waveguide layer or a silicon waveguide layer.

In one embodiment, the integrated circuit unit further includes an electronic integrated circuit (Electronic IC; EIC).

In one embodiment, the electronic integrated circuit and the photonic integrated circuit are separate and individual components.

In one embodiment, the integrated circuit unit further includes a substrate, and the photonic integrated circuit is arranged on the substrate.

In one embodiment, the integrated circuit unit further includes a substrate, and the photonic integrated circuit and the electronic integrated circuit are arranged on the substrate.

In one embodiment, the optical steering structure is an independent and separate component connected to the photonic integrated circuit.

In one embodiment, the optical reflective layer of the optical steering structure includes a metallic reflective layer or a dielectric reflective layer.

In one embodiment, the continuous surface is configured to guide the optical path from a horizontal direction aligned with the waveguide layer to a vertical direction aligned with the photonic integrated circuit.

In one embodiment, the optical steering structure defines a concave surface toward the opening, and the concave surface forms the continuous surface, and the optical reflective layer is partially arranged on the continuous surface, forming the light-transmitting window.

In one embodiment, the optical steering structure further includes a filling material filled in the cavity, wherein the filling material forms the concave surface toward the opening.

In one embodiment, the filling material comprises silica (SiO2), epoxy, polyimide, or a combination of one or more of the above materials.

In one embodiment, the substrate structure further includes one or more waveguide layers, the waveguide layers are stacked along a vertical direction perpendicular to the surface, wherein one waveguide layer includes M waveguides along a first direction, and another waveguide layer includes N waveguides along a second direction; and a plurality of optical turning coupling ports are arranged to the waveguides.

In one embodiment, the first direction and the second direction define an intersection at their projections along the vertical direction, and the optical turning coupling ports are arranged corresponding to the intersections.

The foregoing is merely illustrative and not intended to limit the disclosure. In addition to the illustrative embodiments, examples, and features described above, other embodiments, examples, and features of the disclosure can be clearly understood by referring to the drawings and the following detailed description.

### BRIEF DESCRIPTION OF THE DRAWINGS

FIG. 1 is a schematic side view of a semiconductor device according to a first embodiment of the present invention.

FIG. 2 is a schematic side view of a semiconductor device according to a second embodiment of the present invention.

FIG. 3 is a schematic side view of a semiconductor device according to a third embodiment of the present invention.

FIG. 4 is a schematic side view of a semiconductor device according to a fourth embodiment of the present invention.

FIG. 5 is a schematic side view of a semiconductor device according to a fifth embodiment of the present invention.

FIG. 6 is a schematic side view of a semiconductor device according to a sixth embodiment of the present invention.

FIG. 6A is a partial schematic view of FIG. 6.

FIG. 7 is a schematic side view of a semiconductor device according to a seventh embodiment of the present invention.

### DETAILED DESCRIPTION OF THE DISCLOSURE

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being "connected" to another element, it may be "directly or indirectly mechanically connected" to, or "electrically connected" to the other element, and one or more intervening elements may be present therebetween. It is to be understood that in this specification, the terms "include" or "comprise" specify the stated features, integers, steps, operations, elements and/or components, but do not preclude the presence or addition of one or more other features, integers, steps, operations, elements and/or components, or any combination thereof. The term "and/or" or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

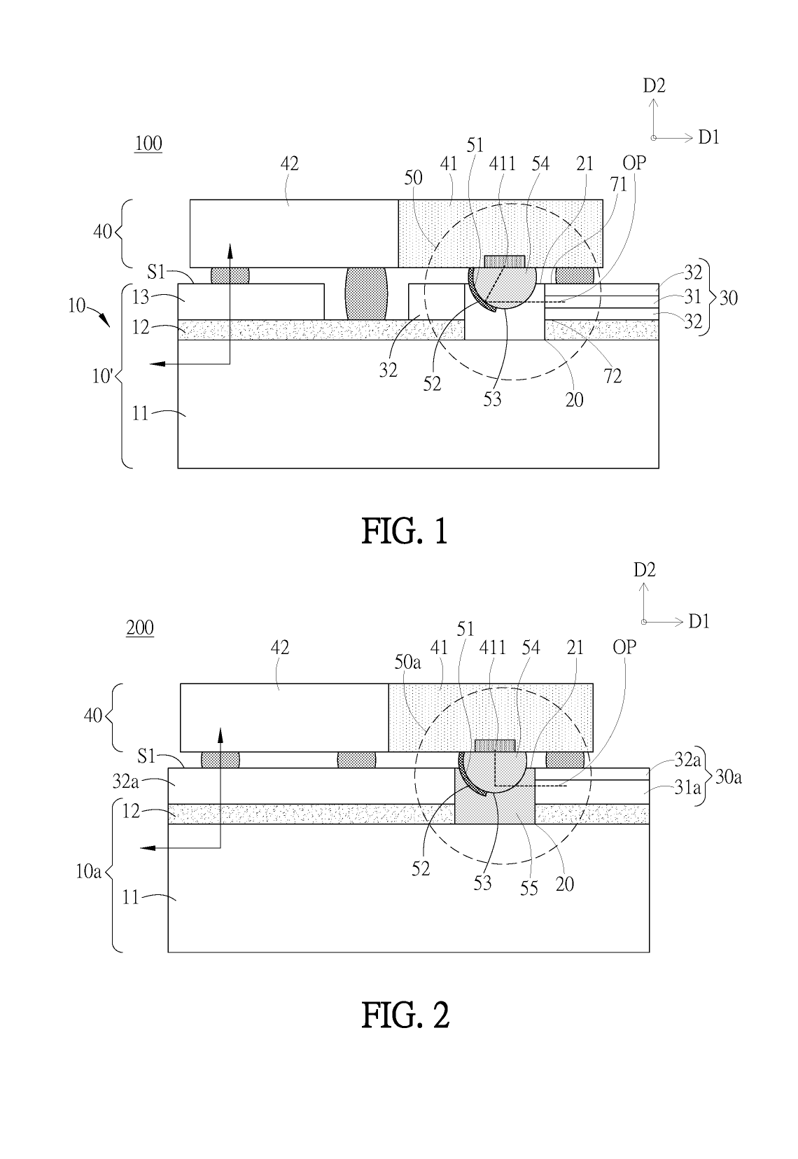

Referring to FIG. 1, a semiconductor device 100 according to a first embodiment of the present invention is shown. The semiconductor device 100 includes a substrate structure 10, a cavity 20, an integrated circuit unit 40, an optical path OP, and an optical steering structure 50. The substrate structure 10 includes a base material layer and a waveguide layer 30 disposed in or on the base material layer. The substrate structure 10 defines a surface S1, which may be an upper surface formed by an intermediate portion of the substrate structure 10 or an overall upper surface of the completed substrate structure 10. As shown in FIG. 1, this embodiment is described by taking the surface S1 as the overall upper surface of the substrate structure 10 and the upper surface of the base material layer as an example. The cavity 20 is disposed in the substrate structure 10, communicates with the waveguide layer 30, and defines an opening 21 on the surface S1. The waveguide layer 30 includes a core layer 31 and at least one cladding layer 32. The integrated circuit unit 40 is disposed above the surface S1 (the term “above” herein means on or over the surface S1). The integrated circuit unit 40 includes a photonic integrated circuit (PIC) 41 corresponding to and facing the opening 21. More specifically, the photonic integrated circuit 41 includes a photoelectric element 411 for optical signal emission or reception, and the photoelectric element 411 corresponds to and faces the opening 21 of the semiconductor device 100. The optical path OP is formed between the photonic integrated circuit 41 and the waveguide layer 30. The optical steering structure 50 is disposed in the cavity 20 for redirecting the optical path OP. The optical steering structure 50 includes a continuous surface 51, a reflective layer 52 disposed on at least a portion of the continuous surface 51, and a light-transmitting window 53 located on the continuous surface 51 and not covered by the reflective layer 52, corresponding to the waveguide layer 30. In other words, the reflective layer 52 is partially disposed on the continuous surface 51, and the light-transmitting window 53 is defined by a region of the continuous surface 51 not surrounded by the reflective layer 52. The continuous surface 51 and the reflective layer 52 are configured to guide the optical path OP from one direction to another and to accommodate different geometries of the optical path OP. In principle, the optical path OP is bidirectional, for example in emission or reception, such that light may be transmitted from the waveguide layer 30 to the photonic integrated circuit 41 or coupled from the photonic integrated circuit 41 to the waveguide layer 30. In this embodiment, the continuous surface 51 is configured to guide the optical path OP from a horizontal direction D1 parallel to the substrate structure 10 and corresponding to the waveguide layer 30 to a vertical direction D2 perpendicular to the substrate structure 10 and corresponding to the photonic integrated circuit.

In some embodiments, the base material layer may include one or more base materials. The waveguide layer 30 is disposed in the base material layer and is coplanar with the surface S1 of the base material layer. For example, in the semiconductor device 100 shown in FIG. 1, the substrate structure 10 includes multiple base materials 11–13. The waveguide layer 30 includes a core layer 31 and upper and lower cladding layers 32 covering the core layer 31. In this embodiment, the base material layer includes a rigid layer 11 and two stacked flexible layers 12 and 13. The rigid layer 11 may include, but is not limited to, glass, ceramic, silicon, silicon oxide, FR4 (Flame Retardant Type 4) glass fiber reinforced epoxy laminate, BT (Bismaleimide-Triazine) resin substrate, or the like. The flexible layer 12 may include, but is not limited to, PI (polyimide), PEN (polyethylene naphthalate), LCP (liquid crystal polymer), PC (polycarbonate), or the like. In this embodiment, the flexible layer 12 is at least partially disposed on the rigid layer 11. The flexible layer 13 and the waveguide layer 30 are partially disposed on the flexible layer 12, and the flexible layer 13 and the waveguide layer 30 are coplanar so that the surface S1 of the substrate structure 10 remains level. At this time, the core layer 31 and the upper and lower cladding layers 32 of the waveguide layer 30 partially cover the flexible layer 12 along the horizontal direction D1. For example, in the semiconductor device 200 shown in FIG. 2, the substrate structure 10a includes base materials 11–12. In this embodiment, the base material layer includes a rigid layer 11 and a flexible layer 12. The waveguide layer 30a is disposed on the flexible layer 12 and includes a core layer 31a and a cladding layer 32a disposed on another side of the core layer 31a. The core layer 31a covers only a portion of the flexible layer 12. Portions of the flexible layer 12 not covered by the core layer 31a may be formed by extension stacking of the cladding layer 32a. In other words, although the core layer 31a is only partially disposed along the planar direction of the flexible layer 12, the unoccupied portions may be compensated by stacking the cladding layer 32a so that the surface S1 remains level. In the present disclosure, the cavity 20 at least penetrates the waveguide layer. In the embodiments of FIGS. 1 and 2, the cavity 20 penetrates the waveguide layer 30 (30a) and the flexible layer 12. The difference between the configurations of waveguide layers 30 and 30a in substrate structures 10 (FIG. 1) and 10a (FIG. 2) is as follows: In substrate structure 10, the waveguide layer 30 is partially disposed on the flexible layer 12; in substrate structure 10a, the waveguide layer 30a is entirely disposed on the flexible layer 12. In substrate structure 10, the core layer 31 is enclosed by upper and lower cladding layers 32; in substrate structure 10a, the core layer 31a is enclosed by the flexible layer 12 and the cladding layer 32a. In some embodiments, the semiconductor device 100 may further include metal reflective layers 71 and 72 disposed on upper and lower surfaces at the interface where the waveguide layer 30 is coupled to the optical steering structure 50 (as shown in FIG. 1, but not limited thereto). In some embodiments, the waveguide layers 30 and 30a include a polymer waveguide layer or a silicon waveguide layer. In particular, the core layer 31 includes a polymer waveguide layer or a silicon waveguide layer.

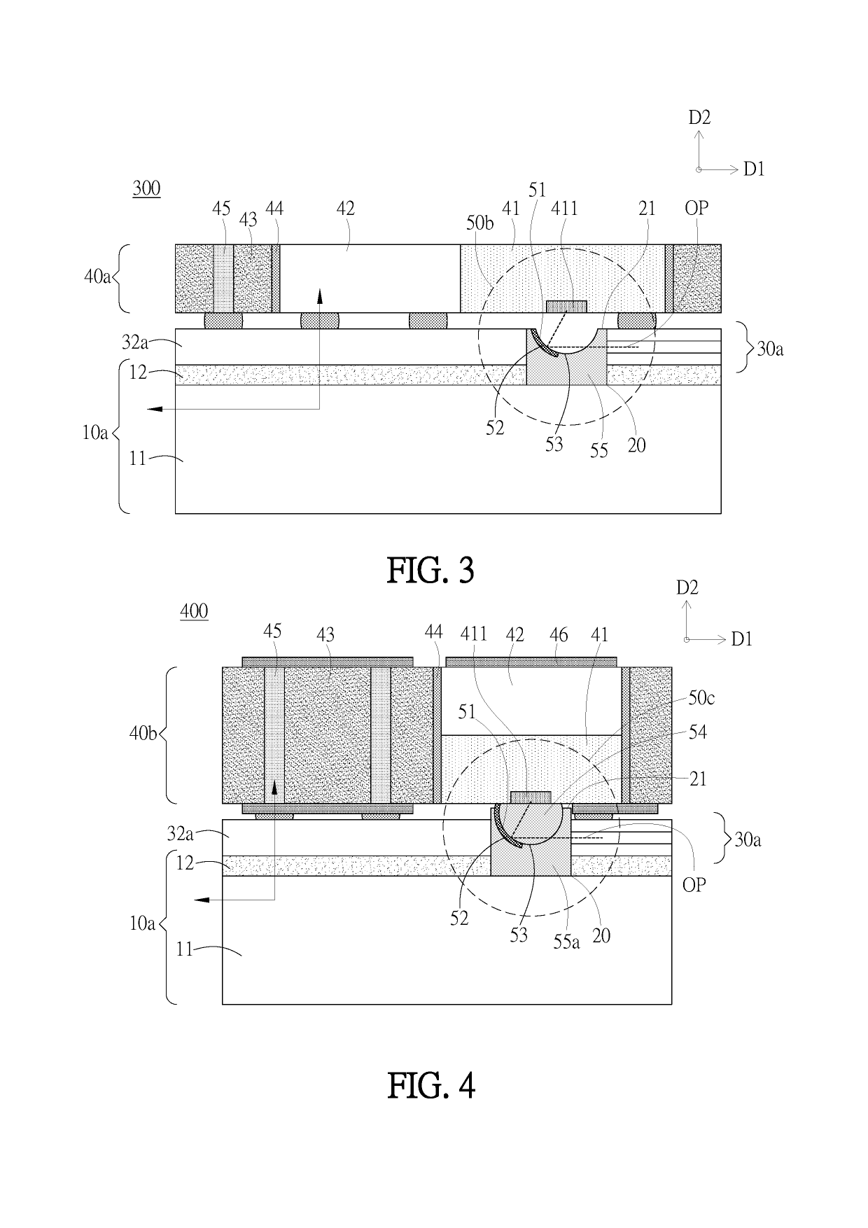

In some embodiments, referring to FIGS. 1 and 2, the integrated circuit unit 40 further includes an electronic integrated circuit 42 (Electronic IC; EIC). The electronic integrated circuit 42 and the photonic integrated circuit 41 may be separate independent components or may be integrated together. In some embodiments, the integrated circuit unit 40a further includes a substrate 43, and the photonic integrated circuit 41 (and/or the electronic integrated circuit 42) is integrated on the substrate 43. Referring to FIG. 3, the photonic integrated circuit 41 and the electronic integrated circuit 42 are arranged coplanarly and integrated in the substrate 43, wherein a filling material 44 is disposed between the substrate 43 and the circuits 41 and 42. The substrate 43 may further include one or more conductive vias 45 for vertical electrical connection. Electrical layers (not shown) may be disposed on upper and lower sides of the integrated circuit unit 40a. As shown in FIG. 4, in the integrated circuit unit 40b, the photonic integrated circuit 41 and the electronic integrated circuit 42 are vertically arranged and integrated in the substrate 43. Similarly, filling material 44 is disposed therebetween, and the substrate 43 includes one or more conductive vias 45 for vertical electrical connection. Electrical layers 46 are disposed on upper and lower sides of the integrated circuit unit 40b.

In brief, the optical steering structure may be a separate component or may be formed attached to the cavity 20. In FIGS. 1 and 2, the optical steering structure is illustrated as a separate component. In FIG. 1, the optical steering structure 50 further includes a solid light-guiding material 54. The continuous surface 51 is formed on an outer surface of the light-guiding material 54, and the reflective layer 52 is formed on a portion thereof. The light-guiding material 54 may be an optically transparent material having an appropriate refractive index, and may include silica (SiO₂), epoxy, polyimide, or a combination thereof. The continuous surface 51 may be a convex surface (including but not limited to a spherical convex surface). The reflective layer 52 may be a metal reflective layer or a dielectric reflective layer. In FIG. 2, the optical steering structure 50a further includes a filling material 55 disposed in the cavity 20. The continuous surface 51, the reflective layer 52, and light-transmitting window 53 are located between the light-guiding material 54 and the filling material 55. The filling material 55 may include silica (SiO₂), epoxy, polyimide, or combinations thereof, and may be the same as or different from the light-guiding material 54. In FIGS. 1 and 2, the light-guiding material 54 may directly contact the photoelectric element 411.

In FIGS. 3 and 4, the optical steering structure may be formed attached to the cavity 20. In FIG. 3, the optical steering structure 50b defines a concave surface (including but not limited to a spherical concave surface) facing the photoelectric element 411 along the opening 21. The concave surface constitutes the continuous surface 51. The reflective layer 52 is disposed on a portion thereof, and the light-transmitting window 53 is defined by portions not covered by the reflective layer 52. The optical steering structure 50b is formed by filling the cavity 20 with a filling material 55. In FIG. 4, the optical steering structure 50c similarly defines a concave surface facing the photoelectric element 411. Unlike FIG. 3, the optical steering structure 50b in FIG. 3 does not extend beyond the surface S1, whereas the optical steering structure 50c in FIG. 4 may extend beyond the surface S1 and further includes a light-guiding material 54 on a side of the reflective layer 52 opposite the filling material 55.

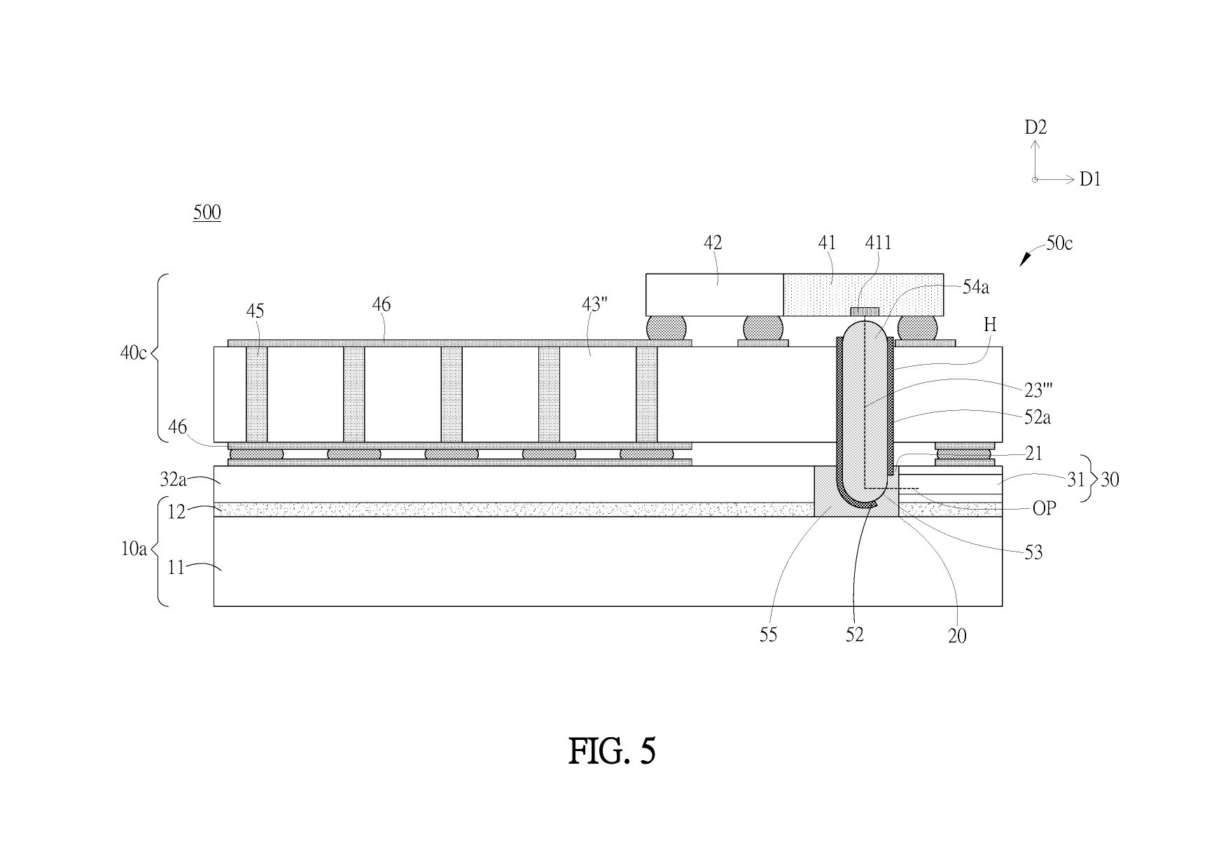

As shown in FIG. 5, in the semiconductor device 500, the integrated circuit unit 40c includes the photonic integrated circuit 41 and the electronic integrated circuit 42 disposed on an upper surface of the substrate 43. The substrate 43 defines a through hole H corresponding to the photonic integrated circuit 41 and the optical steering structure 50c. The substrate 43 further includes conductive vias 45 for vertical electrical connection, and electrical layers 46 are disposed on upper and lower sides of the integrated circuit unit 40c. The optical steering structure 50c includes a continuous light-guiding material 54a extending through the through hole H and the cavity 20. A reflective layer 52a is partially disposed between the light-guiding material 54a and the through hole H and cavity 20, leaving a light-transmitting window 53 coupled to the waveguide layer 30. The optical steering structure 50c further includes a filling material 55 disposed in the cavity 20. The optical steering structure 50c may directly contact the photoelectric element 411 or may be formed from the cavity 20.

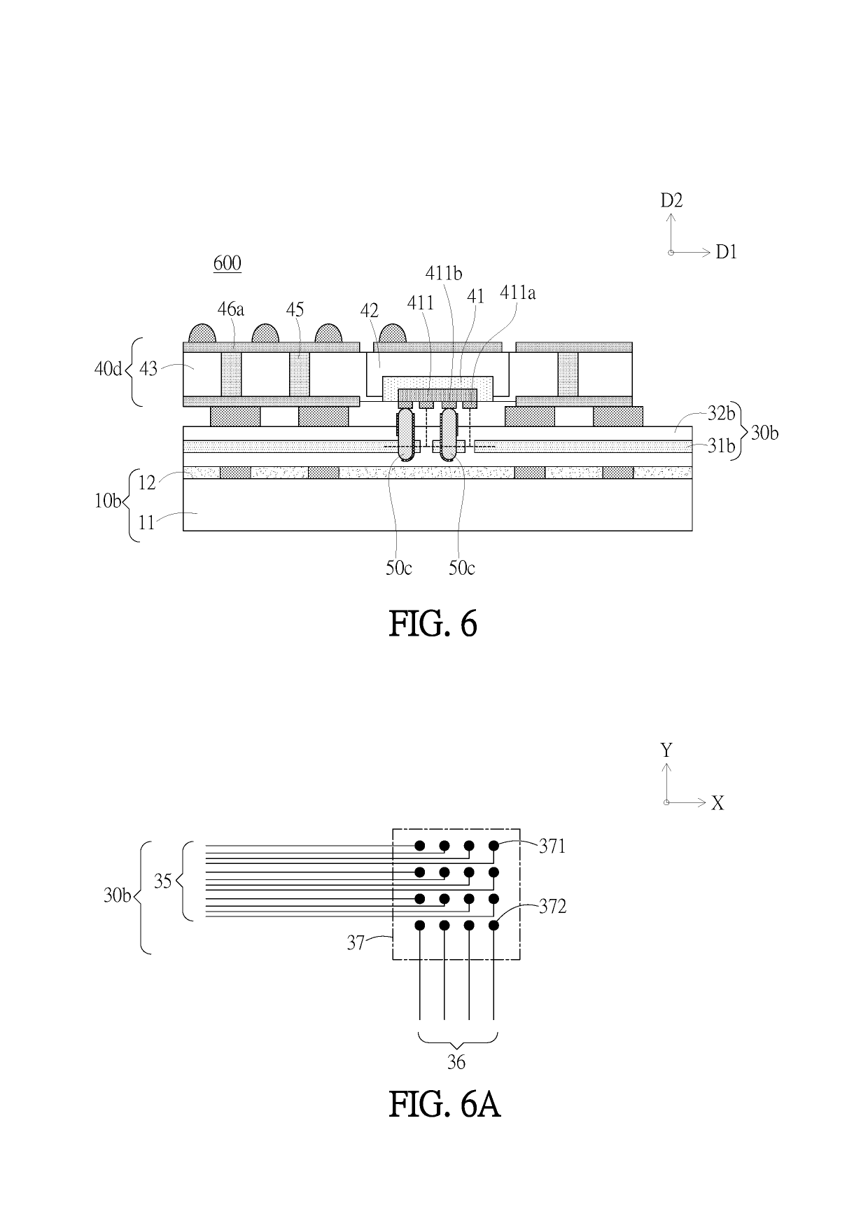

Referring to FIGS. 6 and 6A, in the semiconductor device 600, the integrated circuit unit 40d includes the photonic integrated circuit 41 vertically integrated with the electronic integrated circuit 42, which is integrated into the substrate 43. Filling material (not shown) is disposed at least between the substrate 43 and the electronic integrated circuit 42. The substrate 43 includes conductive vias 45 for vertical electrical connection. Electrical layers 46a are disposed on upper and lower sides of the integrated circuit unit 40d. The photonic integrated circuit 41 includes multiple photoelectric elements 411, including a light-emitting element array 411a and/or a photosensitive element array 411b. The light-emitting element array 411a includes, for example, multiple organic or inorganic light-emitting diodes, and the photosensitive element array 411b includes multiple sensors. Multiple optical steering structures 50c correspond to the photoelectric elements 411 (only some are shown in FIG. 6). The detailed structure may refer to FIG. 5A. The substrate structure 10b includes a base material layer and one or more waveguide layers 30b disposed therein. The base material layer includes a rigid material 11 and a flexible material 12 stacked thereon. The waveguide layers 30b are stacked along a vertical direction D2 perpendicular to the substrate structure 10b (only one waveguide layer 30b is shown). Referring to FIG. 6A, one waveguide layer 30b includes M waveguides 35 extending along a first direction X, and another waveguide layer 30b includes N waveguides 36 extending along a second direction Y. An optical coupling region 37 is formed by multiple optical turning coupling ports 371 and 372 disposed in the waveguides 35 and 36. The coupling ports 371 and 372 respectively correspond to the light-emitting element array 411a and the photosensitive element array 411b via the optical steering structures 50c, and may be active or passive optical coupling elements for switching or distributing optical signals between waveguides. The first direction X and the second direction Y define multiple intersection points when projected along the vertical direction Z, and the optical turning coupling ports 371 and 372 are disposed corresponding to the intersection points.

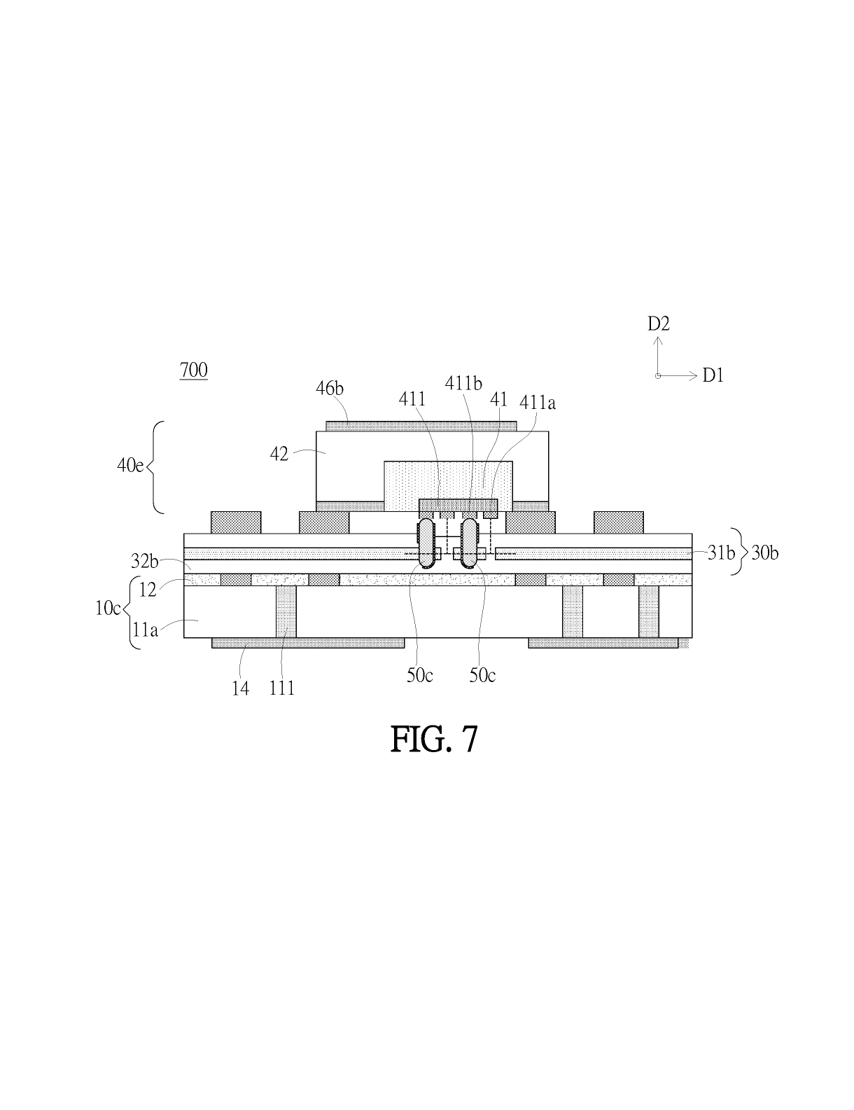

Referring to FIG. 7, in the semiconductor device 700, the integrated circuit unit 40e differs from that of the semiconductor device 600 in that the photonic integrated circuit 41 and the electronic integrated circuit 42 are integrated as a single unit but not integrated into a substrate. Electrical layers 46b are disposed on upper and lower sides of the integrated circuit unit 40e. Details of the integration of the photonic integrated circuit 41 and the electronic integrated circuit 42 may refer to FIG. 6A. The substrate structure 10cincludes a base material layer and one or more waveguide layers 30b disposed thereon. The base material layer includes a rigid material 11 and a flexible material 12 stacked thereon. The waveguide layers 30b are stacked along a vertical direction D2 perpendicular to the substrate structure 10c (only one waveguide layer 30b is shown). In this embodiment, the substrate structure 10c further includes multiple conductive vias 111 for vertical electrical connection disposed in the base material layer. The substrate structure 10c may further include one or more electrical layers 14 disposed on another surface thereof and electrically connected to the conductive vias 111. The waveguide layers 30b are stacked along a vertical direction D2 perpendicular to the surface S1, and the detailed configuration of one waveguide layer 30b may refer to FIG. 6A.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A semiconductor device, comprising:
a substrate structure, including a base material layer and a waveguide layer stacked on the base material layer; the substrate structure defining a surface;
a cavity, arranged in the substrate structure, communicating with the waveguide layer, and defining an opening on the surface of the substrate structure;
an integrated circuit unit arranged above the surface and including a photonic integrated circuit which faces and corresponds to the opening;
an optical path, formed between the photonic integrated circuit and the waveguide layer; and
an optical steering structure, configured in the cavity, for steering the optical path; wherein the optical steering structure includes a continuous surface, an optical reflective layer arranged on at least a portion of the continuous surface, and a light-transmitting window remaining at the continuous surface and corresponding to the waveguide layer; the optical reflective layer are configured to guide the optical path from one direction to another direction.

2. The semiconductor device according to claim 1, wherein the substrate structure defines an electrical layer on the surface.

3. The semiconductor device according to claim 1, wherein the substrate structure has a vertical electrical connection structure inside.

4. The semiconductor device according to claim 1, wherein the waveguide layer is arranged in the base material layer and is aligned with the surface of the base material layer on the same horizontal plane.

5. The semiconductor device according to claim 1, wherein the base material layer includes a rigid layer and a flexible layer stacked over the rigid layer.

6. The semiconductor device according to claim 1, wherein the waveguide layer includes a polymer waveguide layer or a silicon waveguide layer.

7. The semiconductor device according to claim 1, wherein the integrated circuit unit further includes an electronic integrated circuit (Electronic IC; EIC).

8. The semiconductor device according to claim 7, wherein the electronic integrated circuit and the photonic integrated circuit are separate and individual components.

9. The semiconductor device according to claim 1, wherein the integrated circuit unit further includes a substrate, and the photonic integrated circuit is arranged on the substrate.

10. The semiconductor device according to claim 7, wherein the integrated circuit unit further includes a substrate, and the photonic integrated circuit and the electronic integrated circuit are arranged on the substrate.

11. The semiconductor device according to claim 1, wherein the optical steering structure is an independent and separate component connected to the photonic integrated circuit.

12. The semiconductor device according to claim 1, wherein the optical reflective layer of the optical steering structure includes a metallic reflective layer or a dielectric reflective layer.

13. The semiconductor device according to claim 1, wherein the continuous surface is configured to guide the optical path from a horizontal direction aligned with the waveguide layer to a vertical direction aligned with the photonic integrated circuit.

14. The semiconductor device according to claim 1, wherein the optical steering structure defines a concave surface toward the opening, and the concave surface forms the continuous surface, and the optical reflective layer is partially arranged on the continuous surface, forming the light-transmitting window.

15. The semiconductor device according to claim 14, wherein the optical steering structure includes a filling material filled in the cavity, wherein the filling material forms the concave surface toward the opening.

16. The semiconductor device according to claim 15, wherein the filling material comprises silica (SiO2), epoxy, polyimide, or a combination of one or more of the above materials.

17. The semiconductor device according to claim 14, wherein the concave surface is a spherical concave surface.

18. The semiconductor device according to claim 1, wherein the substrate structure further includes one or more waveguide layers, the waveguide layers are stacked along a vertical direction perpendicular to the surface, wherein one waveguide layer includes M waveguides along a first direction, and another waveguide layer includes N waveguides along a second direction; and a plurality of optical turning coupling ports are arranged on the waveguides.

19. The semiconductor device according to claim 18, wherein the first direction and the second direction define an intersection at their projections along the vertical direction, and the optical turning coupling ports are arranged corresponding to the intersections.
